(19) United States
(12) Patent Application Publication
(10) Pub. No.: US 2025/0178156 A1
(43) Pub. Date: Jun. 5, 2025

(54) Chemical Mechanical Polishing Pad

(71) Applicants: DuPont Electronic Materials Holding, Inc., Newark, DE (US); DUPONT SPECIALTY PRODUCTS USA, Wilmington, DE (US); DDP SPECIALTY ELECTRONIC MATERIALS US 8, LLC, Wilmington, DE (US)

(72) Inventors: Philip J. SCOTT, Elkton, MD (US); John R. MCCORMICK, Exton, PA (US); John C. HOWE, Bear, DE (US); Kenneth LAUGHLIN, Wilmington, DE (US)

(21) Appl. No.: 18/952,640

(22) Filed: Nov. 19, 2024

Related U.S. Application Data
(60) Provisional application No. 63/605,276, filed on Dec. 1, 2023.

(51) Int. Cl. B24B 37/24; B33Y 30/00; B33Y 80/00

(52) U.S. Cl. CPC B24B 37/24; B33Y 30/00; B33Y 80/00

(57) ABSTRACT

A chemical mechanical polishing pad comprising a photocured polymer wherein the photocured polymer is the photoinitiated reaction product of a photocurable material comprising molecules having two or more functional groups wherein the functional groups include a thiol group and an ethylenically unsaturated group, provided for at least a portion of the molecules having the ethylenically unsaturated group, the ethylenically unsaturated group is a (meth)acrylate group, wherein the (meth)acrylate groups comprise less than 70 mole percent of total (meth)acrylate, thiol, and ethylenically unsaturated functional groups and wherein the photocure includes reaction of the thiol group with the ethylenically unsaturated group, provided at least some of the molecules comprise three or more functional groups. The chemical mechanical polishing pad can be made by additive manufacturing using stereolithography.

This application claims priority to U.S. Provisional Application No. 63/605,276 filed on Dec. 1, 2023, which is incorporated herein by reference in its entirety.

### FIELD OF THE INVENTION

The invention relates to methods of forming polishing pad for chemical mechanical polishing.

### BACKGROUND OF THE INVENTION

In the fabrication of integrated circuits and other electronic devices, multiple layers of conducting, semiconducting and dielectric materials are deposited onto and removed from a surface of a semiconductor wafer. Thin layers of conducting, semiconducting and dielectric materials may be deposited using a number of deposition techniques. Common deposition techniques in modern wafer processing include physical vapor deposition (PVD), also known as sputtering, chemical vapor deposition (CVD), plasma-enhanced chemical vapor deposition (PECVD) and electrochemical plating, among others. Common removal techniques include wet and dry isotropic and anisotropic etching, among others.

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful for removing undesired surface topography and surface defects, such as rough surfaces, agglomerated materials, crystal lattice damage, scratches and contaminated layers or materials.

Chemical mechanical planarization, or chemical mechanical polishing (CMP), is a common technique used to planarize or polish work pieces such as semiconductor wafers. In conventional CMP, a wafer carrier, or polishing head, is mounted on a carrier assembly. The polishing head holds the wafer and positions the wafer in contact with a polishing layer of a polishing pad that is mounted on a table or platen within a CMP apparatus. The carrier assembly provides a controllable pressure between the wafer and polishing pad. Simultaneously, a polishing medium (e.g., slurry) is dispensed onto the polishing pad and is drawn into the gap between the wafer and polishing layer. To effect polishing, the polishing pad and wafer typically rotate relative to one another. As the polishing pad rotates beneath the wafer, the wafer sweeps out a typically annular polishing track, or polishing region, wherein the wafer's surface directly confronts the polishing layer. The wafer surface is polished and made planar by chemical and mechanical action of the polishing layer and polishing medium on the surface.

Additive manufacture of a polishing layer having porosity or a three-dimensional pattern on the polishing surface has been proposed. For example, one approach uses a droplet jet 3D printing platform. This requires relatively low viscosity materials that are then photocured. The material applied is then photocured. Examples of photocurable systems suitable for use with such droplet jet 3D printing can include acrylates, methacrylates, or epoxides as reactive groups for photocuring. See e.g., US2019/0224809, US2020/0157265, US2021/0205951, U.S. Pat. No. 11,612,978, and US2019/0337117. These chemistries generally undergo chain-growth photocuring. This can result in materials having limited toughness and elongation properties that can result in undesirably high wear rates.

Another approach uses vat polymerization (including digital light process and stereolithographic approaches to additive manufacture). See e.g., U.S. Pat. No. 10,350,823. Examples of photocurable systems useful in this method include a composition of acrylate blocked isocyanates and acrylate monomers that can be photopolymerized via acrylate or methacrylate groups. See e.g., US 2022/0119586. Polymers cured by free radical initiated reaction of acrylate or methacrylate groups with each other can have poor toughness and elongation making them less suitable for use as polishing layers in chemical mechanical polishing pads.

It would be desirable to have chemical mechanical polishing pads that can be produced by additive manufacturing where the pads have good toughness, elongation and wear rate (e.g., toughness, elongation, wear rate are similar to or better than those for commonly used chemical mechanical polishing pads).

It would also be desirable to have an additive manufacturing process for making a polishing layer for a chemical mechanical polishing pad that enables better toughness, better elongation, wear rate, and more flexibility in tuning mechanical properties of the polishing layer. Particularly, it would be desirable to have a method for additive manufacturing of a polishing layer for chemical mechanical polishing that provided mechanical properties similar to those of common non-photocured polishing layers in chemical polishing pads.

### SUMMARY OF THE INVENTION

Disclosed herein is a chemical mechanical polishing pad comprising a photocured polymer wherein the photocured polymer is the photoinitiated reaction product of a photocurable material comprising molecules having two or more functional groups wherein the functional groups include a thiol group and an ethylenically unsaturated group, provided for at least a portion of the molecules having the ethylenically unsaturated group, the ethylenically unsaturated group is a (meth)acrylate group. The (meth)acrylate groups comprise less than 70 mole percent of total (meth)acrylate, thiol, and ethylenically unsaturated functional groups. The photocure includes reaction of the thiol group with the ethylenically unsaturated group. At least some of the molecules comprise three or more functional groups.

Also disclosed is the polishing pad of the above paragraph formed from a method comprising providing a photocurable material in a vessel, selectively curing by irradiation a portion of the photocurable material to form a cured structure, selectively curing by irradiating an additional portion of the photocurable material to further build the cured structure, repeating the selective curing by irradiation until the cured structure has the form of an element of the polishing pad. For example, the element of the polishing pad can be a polishing layer or a subpad layer, or both.

### BRIEF DESCRIPTION OF DRAWINGS

FIG. 1 is a schematic of a top-down additive manufacturing apparatus as disclosed herein.

FIG. 2 is a schematic of a bottom-up additive manufacturing apparatus as disclosed herein.

### DETAILED DESCRIPTION OF THE INVENTION

The chemical mechanical polishing pad disclosed herein includes a polymer wherein the cure of the polymer includes reaction of thiol groups with (meth)acrylate groups, rather than simply by free radial initiated reaction of two (meth)acrylate groups. “(Meth)acrylate” as used herein is a term designating a genus that includes acrylate, methacrylate, or mixtures including both acrylate and methacrylate.

The reaction mixture used to form the photocured polymer can be suitable for additive manufacturing, including particularly stereolithography or vat polymerization methods.

The photocured polymer can be formed by reaction of molecules having two or more functional groups where the functional groups are ethylenically unsaturated groups and thiol groups. For example, the molecules have two or more functional groups can include both at least one ethylenically unsaturated group and also at least one thiol group. This molecule can be considered an AB type molecule. As another example the molecules having two or more functional groups include a molecule (A) having two or more ethylenically unsaturated groups and a molecule (B) having two or more thiol groups. An AB type molecule can be used in combination with a molecule (A), in combination with a molecule (B) or in combination with both a molecule (A) and a molecule (B). To provide cross-linking at least a portion of the molecules can have at least three of the reactive groups (i.e., at least three ethylenically unsaturated groups on a molecule, at least three thiol groups, at least two ethylenically unsaturated groups and one thiol group on a molecule or at least two thiol groups and one ethylenically unsaturated group on a molecule). The relative amounts of di-functional (i.e., molecules having two ethylenically unsaturated groups or molecules having two thiol groups) to higher functional (e.g., molecules having more than two ethylenically unsaturated groups or molecules having more than two thiol groups) molecules enables control of cross-link density. At least a portion of the ethylenically unsaturated groups are (meth)acrylate groups.

The molecule (A) can comprise an oligomer (also referred to as pre-polymer), a monomer, or a mixture thereof. The molecule (B) can comprise an oligomer (also referred to as pre-polymer), a monomer, or a mixture thereof. By selection of the oligomer and monomer structures and their relative amounts, the properties of the photocured polymer can be tuned. For example, rigid multifunctional alkenes used as molecule (A) can provide improved hardness or toughness. When using an oligomer molecule (A), mixing with a monomer molecule (A) can be useful for viscosity control while avoid using of a solvent that may need to be removed after cure.

A molecule (A) can include, for example, a vinyl group, a vinyl ether group, an allyl group, an allyl ether, an allyl ester, a maleimide, a vinyl sulfone, a norbornene, provided the reaction mixture includes at least some (meth)acrylate groups on molecules (A), (AB), or both (A) and (AB). A monomeric molecule (A) can include diallyl phthalate, diallyl isophthalate, diallyl terephthalate, diallyl ether, trimethylolpropane diallyl ether, 1,4-butanediol divinyl ether, di(ethylene glycol)divinyl ether, tri (ethylene glycol)divinyl ether, 1,4-cyclohexanedimethanol divinyl ether, 3,9-divinyl-2,4,8,10-tetraoxaspiro[5.5] undecane, 1,3,5-triallyl-1,3,5-triazine-2,4,6 (1H,3H,5H)-trione, 2,4,6-Triallyloxy-1,3,5-triazine, N,N′-methylenebis(acrylamide). Examples of monomers (A) having (meth)acrylate groups include aliphatic or aromatic compositions between (meth)acrylate groups and can be for example aliphatic multifunctional acrylates such as 1,3-propanediol diacrylate, 1,4-butanediol diacrylate, 1,5-pentanediol diacrylate 1,6-hexanediol diacrylate, trimethylolpropane triacrylate, alkylene oxide multifunctional acrylates such as ethylene glycol diacrylate, di(ethylene glycol) diacrylate, tri (ethylene glycol) diacrylate, tri (propylene glycol) diacrylate, cyclic aliphatic acrylates such as 2-[5-[(acryloyloxy)methyl]-5-ethyl-1,3-dioxan-2-yl]-2-methylpropyl acrylate, tricyclodecane dimethanol diacrylate, and aromatic (meth)acrylates such as biphenyl-4,4′-diyl bis(2-methylacrylate). These monomeric molecules (A) can be used in a mixture with an oligomeric molecule (A). An oligomeric molecule (A) can be, for example, poly(ethylene glycol) diacrylate, poly(propylene glycol) diacrylate, poly(tetramethyleneoxide)diacrylate, poly(dimethylsiloxane) diacrylate, polycaprolactone diacrylate, or a urea-, urethane- or thiourea-containing oligomer.

Advantageously, a multi-functional isocyanate can be reacted to form a urea-, urethane-, or thiourea-containing molecule A by reacting with a molecule (i.e., an end capping agent) comprising ethylenic unsaturation (e.g., a (meth)acrylate group) and at least one nucleophilic functional group (e.g., amine, hydroxy, thiol, or the like). Examples of the capping agent include allyl phenols (e.g., 2-allyl phenol, 4-allyl phenol, eugenol, isoeugenol), alkylene glycol allyl ethers (e.g., ethylene glycol allyl ether), alkylene glycol monovinyl ethers (e.g., ethylene glycol monovinyl ether, butanediol monovinyl ether) allyl alcohols (e.g., 1-allyl cyclohexanol, allyl alcohol, 3-buten-1-ol, 4-penten-1-ol, 2-methyl-3-buten-1-ol, 5-hexen-1-ol), allyl amines, 1-allyl-2-thiourea, N-allyl-N′-(2-hydroxyethyl)thiourea, hydroxyalkyl (meth)acrylates (e.g., hydroxyethyl acrylate, hydroxyethyl methacrylate), hydroxyl norbornene compounds such as 5-norbornene-2-methanol, or a mixture thereof.

The ethylenic unsaturation in molecule (A) or molecule (AB) can comprise for example, a vinyl group, a vinyl ether group, an allyl group, an allyl ether, an allyl ester, a maleimide, a norbornene, a (meth)acrylate, provided at least a portion of the ethylenically unsaturated groups in the reaction mixture comprise (meth)acrylate groups. Allyls, allyl ethers, and allyl esters can provide a good balance of shelf stability and photo-reactivity. Allyl group as used herein means the group —CH₂—CH—CH₂. Monosubstituted alkenes can provide rapid reaction with the thiol groups while disubstituted alkenes such as crotyl alcohol, trans-3-hexnen-1-ol, will react at a lower rate.

For example, to prepare a molecule (A) the following reaction scheme can be used:

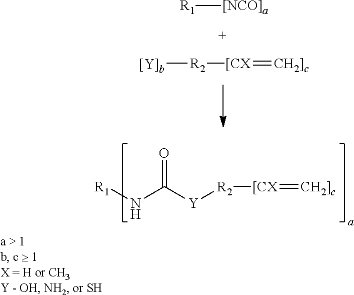

R₁ is a linking group. For example, R₁ can comprise an aliphatic group or an aromatic group or both. For example, R₁ can comprise a divalent alkyl, a cycloalkyl, a divalent aryl, a divalent arylalkyl, or can comprise carbons and a heteroatom such as nitrogen. For example, R₁ can be methylene diphenyl, isophorone, 2,4-toluene, 2,6-toluene, hexamethyl, or uretidione backbones formed from the dimerization of two isocyanate groups. Alternatively, R₁ can be an oligomeric group comprising 2 or more repeat units, 3 or more, up to 150 repeat units. The repeat units can be, for example, alkylene oxides such as ethylene-, propylene-, or tetramethylene oxide, lactones such as caprolactone, saturated and unsaturated forms of hydrocarbon and diene units such as butadiene, isoprene, ethylidene norbornene, dicyclopentadiene, vinyl norbornene, siloxanes such as dimethylsiloxane, and fluorinated units such as vinylidene fluoride and tetrafluoroethylene. R₂ is a linking group. For example, R₂ can comprise an aliphatic group or an aromatic group or both. For example, R₂ can be a divalent alkyl, a divalent aryl, a divalent arylalkyl such as benzyl, phenyl, alkyl, cycloaliphatics such as cyclohexyl. R₂ is provided initially in an end capping agent of the formula [Y]_{b}—R₂—[C═C]_{c}. Generally, an end capping agent can include at least one nucleophile (e.g., OH, NH₂, or SH) and an ethylenically unsaturated group. Examples of end-capping agents that provide (meth)acrylates include hydroxyalkyl (meth)acrylates (e.g., hydroxyethyl acrylate, hydroxyethyl methacrylate).

For example, to form a molecule (A) monomer, a polyisocyanate monomer (e.g., diisocyanate monomer) can be reacted to form a monomer having at least two ethylenically unsaturated groups (e.g., (meth)acrylate groups). Examples of such polyisoscyanate monomers include toluene diisocyanate (TDI) (e.g., 2,4-toluene diisocyanate; 2,6-toluene diisocyanate), diphenylmethane diisocyanate (MDI) (e.g., 4,4′-diphenylmethane diisocyanate); 4,4′-diisocyanato dicyclohexylmethane (H12MDI); naphthalene-1,5-diisocyanate; tolidine diisocyanate; para-phenylene diisocyanate; xylylene diisocyanate; isophorone diisocyanate; hexamethylene diisocyanate; 4,4′-dicyclohexylmethane diisocyanate; cyclohexanediisocyanate; and mixtures thereof.

As another example, the molecule (A) can comprise an oligomer of a urethane or urea-based pre-polymer having two or more ethylenically unsaturated groups; polysiloxane, such as polydimethylsiloxane, having two or more ethylenically unsaturated groups (e.g., (meth)acrylate groups); or a polyalkylene glycol two or more ethylenically unsaturated groups. Where urethane or urea chemistry are desired, such a molecule (A) oligomer can be derived from an isocyanate prepolymer, such as a polyalkylene glycol end-capped with isocyanate groups or a small molecule diisocyanate. Examples of diisocyanates used directly or as prepolymer endcaps include. The isocyanate-terminated urethane prepolymer can have 2 to 30 wt % unreacted isocyanate (NCO) groups. The prepolymer polyol used to form the polyfunctional isocyanate terminated urethane prepolymer can be selected from the group consisting of diols, polyols, polyol diols, copolymers thereof and mixtures thereof. For example, the prepolymer polyol can be selected from the group consisting of polyether polyols (e.g., poly(oxytetramethylene)glycol, poly(oxypropylene)glycol and mixtures thereof); polycarbonate polyols; polyester polyols; polycaprolactone polyols; mixtures thereof; and, mixtures thereof with one or more low molecular weight polyols selected from the group consisting of ethylene glycol; 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and, tripropylene glycol. For example, the prepolymer polyol can be selected from the group consisting of polytetramethylene ether glycol (PTMEG); ester-based polyols (such as ethylene adipates, butylene adipates); polypropylene ether glycols (PPG); polycaprolactone polyols; copolymers thereof; and mixtures thereof. For example, the prepolymer polyol can be selected from the group consisting of PTMEG and PPG. Examples of commercially available PTMEG based isocyanate terminated urethane prepolymers include Imuthane® prepolymers (available from COIM USA, Inc., such as, PET-80A, PET-85A, PET-90A, PET-93A, PET-95A, PET-60D, PET-70D, PET-75D); Adiprene® prepolymers (available from Lanxess, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70APLF, 75APLF. Non-TDI based isocyanate terminated urethane prepolymers can also be used. For example, isocyanate terminated urethane prepolymers include those formed by the reaction of 4,4′-diphenylmethane diisocyanate (MDI) and polyols such as polytetramethylene glycol (PTMEG) or diols such as 1,4-butanediol (BDO), are acceptable. Modified MDI products such as polycarbodiimide-modified MDI (e.g. Isonate 143L) and quasi-prepolymers of MDI reacted with low molecular weight diols (e.g. Isonate 181) such as 1,2-propylene glycol; 1,3-propylene glycol; 1,2-butanediol; 1,3-butanediol; 2-methyl-1,3-propanediol; 1,4-butanediol; neopentyl glycol; 1,5-pentanediol; 3-methyl-1,5-pentanediol; 1,6-hexanediol; diethylene glycol; dipropylene glycol; and tripropylene glycol or combinations thereof can be used. Commercial examples of MDI, polymeric MDI, and MDI prepolymers include ISONATE™ 143L, ISONATE™ 143LP, ISONATE™ 181, ISONATE™ 240, ISONATE™ M 143, ISONATE™ M 320, ISONATE™ M340, ISONATE™ 342, ISOBIND™ 1002, ISOBIND™ 1013, ISOBIND™ 1014, ISOBIND™ 1088, ISOBIND™ 1100, ISOBIND™ 1100 S, ISOBIND™ 1200R, PAPI™ 135, PAPI™ 135C, PAPI™ 17, PAPI™ 20, PAPI™ 27, PAPI™ 580 N, PAPI™ 6146, PAPI™ 901, PAPI™ 94, POLYMERIC MDI 199, POLYMERIC MDI 253, VORANATE™ M 200, VORANATE™ M 220, VORANATE™ 229, VORANATE™ 229 N, VORANATE™ M 230, VORANATE™ M 2940, VORANATE™ M 580, VORANATE™ M 595, VORANATE™ M 600, VORANATE™ M 647, VORANATE™ SD 100, VORANATE™ SD 100 IF from The Dow Chemical Company. Prepolymers can include at least two isocyanate groups. Some commercially available products may include undisclosed mixture of molecules with two isocyanate groups with molecules having more than two isocyanate groups. An example of commercial prepolymer believed to have greater than two isocyanates per molecule is Desmodur N-3400 from Covestro AG.

Examples of molecule (B) include but are not limited to alkyl multifunctional thiols (e.g., 1,2-ethanedithiol, 1,3-propanedithiol, propane-1,2,3-trithiol, 1,4-butanedithiol, 1,5-pentanedithiol, 1,6-hexanedithiol, cyclohexane-1,4-diyldimethanethiol), mercaptopropionate esters (e.g., ethylene glycol bis(3-mercaptopropionate), trimethylolpropane tris(3-mercaptopropionate), pentaerythritol tetrakis(3-mercaptopropionate), tris [2-(3-mercaptopropionyloxy)ethyl] isocyanurate, thioglycolate esters (e.g., 1,4-butanediol bis(thioglycolate)), mercaptoacetate esters (e.g., pentaerythritol tetrakis(mercaptoacetate)), aromatic dithiols, arylalkyl (e.g. aryl with alkylthiol pendant groups) (e.g., 1,3-benzenedimethanethiol, 1,4-benzenedimethanethiol, 4,4′-bis(mercaptomethyl) biphenyl) and thiol-terminated oligomers (e.g., poly(ethylene glycol)dithiol, poly(dimethylsiloxane)dithiol or urethane or urea oligomer).

Examples of AB type molecules include allyl mercaptan and oligomers or prepolymers capped with both an ethylenically unsaturated group and a thiol group. The oligomers capped with both an ethylenically unsaturated group and a thiol group can be prepared as discussed above but providing one capping group comprising ethylenic unsaturation and one capping group with thiol functionality.

The photocured polymer can be formed from a reaction mixture comprising one or more molecule (A), one or more molecule (B) and a photoinitiator. The photoinitiator absorbs activating wavelengths of radiation (e.g., ultraviolet radiation, at wavelength of for example 200-500, 340-390 (e.g., at 385 nanometers (nm)).

The reaction mixture further comprises a photoinitiator. According to a first embodiment the photoinitiator is a free radical generator. In that instance the cure will include reaction of the thiol group with the (meth)acrylate to form a thiol-ether bond. In this instance cure may also include reaction of (meth)acrylate groups with other (meth)acrylate groups. Examples of radical generating photoinitiators include phenyl bis(2,4,6-trimethylbenzoyl)-phosphine oxide (PPO), diphenyl(2,4,6-trimethylbenzoyl) phosphine oxide (TPO), 2,2-dimethoxy-2-phenylacetophenone (DMPA), 2-isopropylthioxanthone (ITX), and benzoyl peroxide. As another example, the photoinitiator, upon radiation can produce a base that can deprotonate one of the thiol groups leading to reaction of thiol with a meth (acrylate) group. This approach can avoid side reactions of meth (acrylate) groups with each other. Examples of photo base generators include 1,2-dicyclohexyl-4,4,5,5-tetramethylbiguanidium n-butyltriphenylborate (e.g., Fujifilm WPBG-300), (Z)-{[bis(dimethylamino)methylidene] amino}-N-cyclohexyl(cyclohexylamino) methaniminium tetrakis(3-fluorophenyl) borate (e.g., Fujifilm WPBG-345), (e.g., 1,2-diisopropyl-3-[bis(dimethylamino)methylene] guanidium 2-(3-benzoylphenyl) propionate (e.g., Fujifilm WPBG-266), 9-anthrylmethyl N,N-diethylcarbamate (e.g., Fujifilm WPBG-018). In cases where the photobase generator does not absorb at the application wavelength, a photosensitizer can be used, for example thioxanthone species, or other photobase generators that do absorb at the target wavelength. In cases where the photobase generator generates radicals in addition to bases, radical inhibitor species such as 2,2,6,6-tetramethylpiperidine 1-oxyl (TEMPO) can be used to selectively inhibit radical side reactions while allowing base-catalyzed reactions. The amount of photoinitiator in the reaction mixture can be, for example, from 0.1, from 0.2, from 0.3, from 0.4 or from 0.5 up to 5, up to 4, up to 3, up 2, or up to 1.5 weight percent based on total weight of the reaction mixture.

The mole ratio of the ethylenically unsaturated groups as least a portion of that are (meth)acrylate groups (e.g., from the molecules (A)) to the thiol groups (e.g., of the molecules (B)) can be from 0.5:1 to 1:0.5, 0.6:1 to 1:0.6, 0.7:1 to 1:0.7. 0.8:1 to 1:0.8, 0.9:1 to 1:0.9, 0.95:1 to 1:0.95, or can be about 1:1. The mole percent of meth (acrylate) groups based on total (meth)acrylate, thiol, and ethylenically unsaturated functional groups [total moles of (meth)acrylate groups plus moles of other ethylenically unsaturated groups plus moles of thiol groups] can be less than 70%, or less than 60% or less than 55% and is preferably at least 1%. In certain embodiments, such as when a photobase generator is used, the mole ratio of meth (acrylate) groups based on total moles of (meth)acrylate groups, other ethylenically unsaturated groups and thiol groups is preferably at least 30%, more preferably at least 40%.

The reaction mixture can optionally include a UV absorber in addition to the photoinitatior. The UV absorber can facilitate tuning of light penetration (i.e., cure depth) for the reaction mixture. The UV absorber can absorb light, for example, at the wavelength used in the additive manufacture device (e.g., 385 nm). Examples of UV absorbers include 2,2′-Dihydroxy-4,4′-dimethoxybenzophenone (DHDMBP) and avobenzone. The amount of UV absorber can be from greater than 0, at least 0.1, at least 0.2, at least 0.3, at least 0.4, or at least 0.5 up to 10, up to 5, or up to 2 wt % based on total weight of the reaction mixture.

The reaction mixture can optionally include a liquid reactive diluent that contains a group (e.g., ethylenic unsaturated group or thiol) that reacts with the other components of the reaction mixture. This liquid reactive diluent can enable viscosity reduction of the reaction mixture to control the viscosity of the reaction mixture. Since the liquid reactive diluent reacts with the other components of the reaction mixture it does not need to be removed after forming the polishing layer. Such removal could cause shrinkage. One type of liquid reactive diluents includes molecules containing ethylenically unsaturated groups such as (meth)acrylate, allyl, allyl ether, vinyl, and vinyl ether compounds. Examples of these include but are not limited to alkyl (meth)acrylates, hydroxyalkyl (meth)acrylate where the alkyl has 1 to 4 carbon atoms, vinyl toluene, isononyl (meth)acrylate, (meth)acrylic acid, diallyl isophthalate, diallyl terephthalate, butane diol divinyl ether N-vinyl pyrrolidone, butanediol monovinyl ether, ethylene glycol vinyl ether, vinyl acetate, 1-vinylimidazole, 2-vinyl pyrazine, vinyl pivalate, vinyl propionate, vinyl stearate, vinyl decanoate, ethyl vinyl ether, propyl vinyl ether, butyl vinyl ether, allyl ether, allyl hexanoate, allyl acetate, allyl butyl ether, allyl mercaptan, pentaerythritol allyl ether, allyl methyl carbonate, allyl phenyl ether, allyl heptanoate, allyl butyrate, allyl methyl sulfone, allyl sulfide, tetrahydrofurfuryl acrylate, N,N-dimethylacrylamide, N,N-dimethylacrylamide, isobornyl acrylate, 2-hydroxylethyl acrylate, and 2-hydroxyethyl methacrylate. Another type of liquid reactive diluent can comprise liquid thiol compounds such as 1,2-ethanedithiol, 1,3-propanedithiol, 1,4-butanedithiol, 1,5-pentanedithiol, 1,6-hexanedithiol, mercaptopropionic acid, mercaptopropionate esters. The liquid reactive diluent can be present in amounts of 0 to 50%, or 1 to 40%, or 2 to 30%, or 3 to 20%, or 4 to 15% or 5 to 10% based on total weight of the reaction mixture.

The reaction mixture may also include unreactive diluents (e.g., solvents such as dimethyl sulfoxide (DMSO), dimethylformamide (DMF), N-methyl pyrrolidone (NMP), acetone, etc. to lower viscosity. However, this can add the step of solvent removal to the process of forming the polishing layer.

The reaction mixture can also include non-reactive components that are desired to be included in the polishing layer. The components can add functionality such as mechanical reinforcement, porosity, or additional abrasives for polishing. Examples of these include inorganic particles such as silica, ceria, titania; polymeric beads or particles; expandable polymeric microspheres and the like.

One example of a reaction scheme using a radical generating photoinitiator to form a composition useful as an element in a polishing pad is as disclosed herein is as follows:

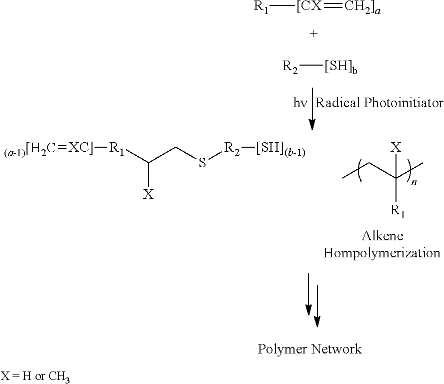

wherein a and b are integers of 2, 3, 4, 5, or 6, provided to get crosslinking at least some of a and b must be 3, 4, 5, or 6, R1 is a multivalent linking group consistent with the description of molecules (A), and R2 is a multivalent linking group consistent with the description of molecules (B).

Where a photobase generator is used, the following is a representative reaction scheme:

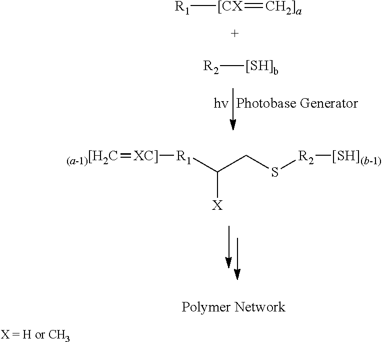

wherein a and b are integers of 2, 3, 4, 5, or 6, provided to get crosslinking at least some of a and b must be 3, 4, 5, or 6, R1 is a multivalent linking group consistent with the description of molecules (A), and R2 is a multivalent linking group consistent with the description of molecules (B).

The cured polymers as described herein that can be used as polishing layers in a polishing pad can have a glass transition temperature (Tg) according to ASTM D5279-21 and selecting the temperature at maximum tan delta of, for example, from −20° C., or from −10 up to 120, up to 100, up to 70, up to 60, or up to 50° C. The cured polymers as described herein that can be used as polishing layers in a polishing pad can have a tensile modulus according to ASTM D412-05 of, for example, from 1, from 5 or from 10 up to 700, up to 500, or up to 400 megapascals (MPa). The cured polymers as described herein that can be used as polishing layers in a polishing pad can have an elongation according to ASTM D412 of, for example, from 20, from 50, from 70 or from 100 up to 500, up to 450, up to 400, or up to 300%. The cured polymers as described herein that can be used as polishing layers in a polishing pad can have a toughness according to ASTM D412 of, for example from 1, from 2, or from 5 up to 30, or up to 20 MPa. The cured polymers as described herein that can be used as polishing layers in a polishing pad can have a cut rate as described herein of, for example, from greater than 0 up to 2, up to 1.5, up to 1 millimeters per hour (mm/h).

A method of making a chemical mechanical polishing pad as disclosed herein is also provided. The method comprises comprising providing a photocurable material in a vessel, selectively curing by irradiation with activating wavelengths of radiation a portion the photocurable material to form a cured structure, selectively curing by irradiation an additional portion of the photocurable material to further build the cured structure, repeating the selective curing by irradiation until the cured structure has the form of an element of the polishing pad, wherein the photocurable material comprises molecules having two or more functional groups wherein the functional groups are ethylenically unsaturated groups (at least a portion of that are (meth)acrylate groups and thiol groups, provided at least some of the molecules comprise three or more functional groups where the irradiation leads to reaction of the ethylenically unsaturated group with the thiol group. The photocurable material in the vessel can be a liquid. The photocurable material in the vessel can be flowable under printing conditions. The photocurable material in the vessel can be spreadable.

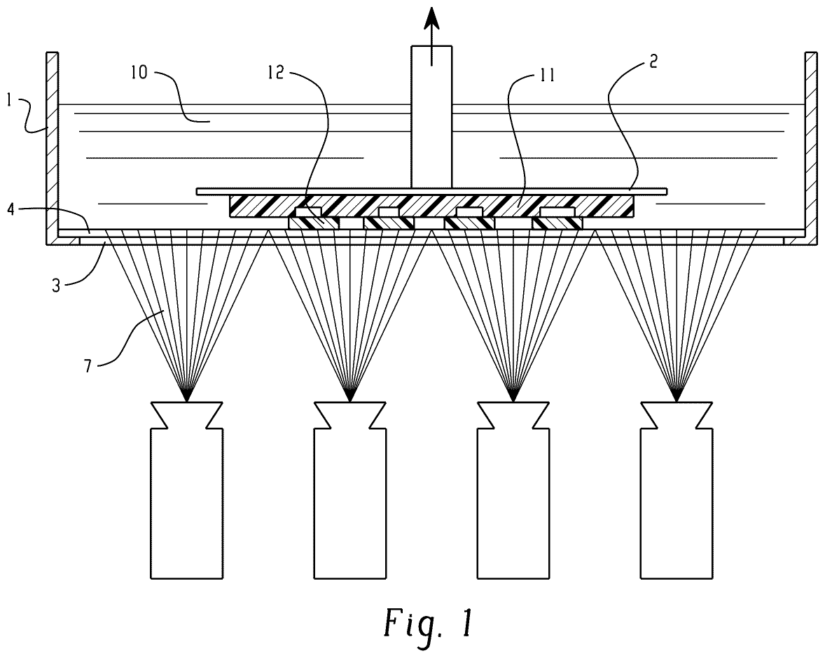

Thus, in one example, as shown in FIG. 1, a bottom-up additive manufacturing apparatus includes vessel 1. Vessel 1 has a portion 3 that is transparent to activation radiation 7. The portion 3 can be at the bottom of the vessel 1. The vessel 1 contains a reaction mixture 10 as described herein (i.e., the reaction mixture comprises a mixture of molecules having two or more functional groups wherein the functional groups are ethylenically unsaturated groups (at least a portion of that are (meth)acrylate groups) and thiol groups and the reaction is the reaction of the ethylenically unsaturated group and the thiol group. This reaction mixture can be initiated by exposure to radiation. The reaction mixture can include a photoinitiator that generates a free radical upon exposure to activating wavelengths of radiation). The activation radiation 7 is passed through the portion 3 of the vessel 1, in an image-wise manner to photocure a portion of the reaction mixture 10 at or immediately above the bottom of the vessel 1. Optionally, a layer 4 may be provided above the surface 3. The layer 4 can prevent sticking of the photocured polymer to the portion 3. The layer 4 can be for example a liquid immiscible with the reaction mixture or a low surface energy coating. The layer 4 is also transparent to the activation radiation 7. A first layer 11 of photocured polymer is formed under a build platform 2. The build platform 2 and first layer 11 are raised allowing the reaction mixture 10 to flow under the first layer 11. Radiation is again passed through the surface 3 in an image-wise manner to form a second layer 12 of the photocured polymer. This is repeated to form additional layers until the desired element of the polishing pad (e.g., a polishing layer) is fully formed.

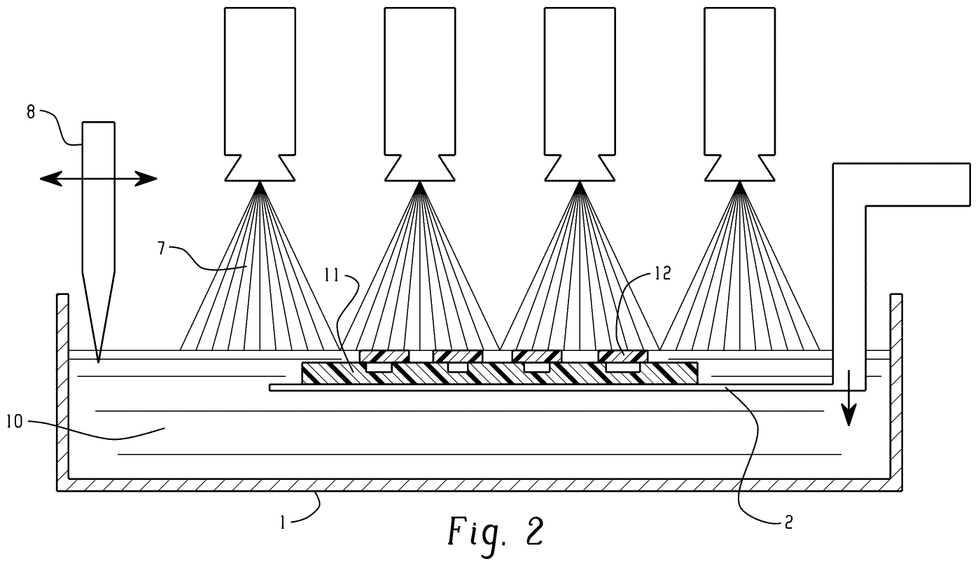

In another example as shown in FIG. 2 a top-down additive manufacturing apparatus includes vessel 1. Vessel 1 contains the reaction mixture 10 as described herein. A layer of the reaction mixture 10 is provided above the build platform 2 and image-wise exposed to radiation 7 to form a first layer 11 of the photocured polymer on the build platform 2. The build platform 2 is then lowered allowing an additional layer of the reaction mixture 10 to cover the first layer 11. A recoating blade 8 can be used to ensure the reaction mixture 10 fully covers the first layer 11. This is particularly helpful for viscous reaction mixtures. The reaction mixture is then again image-wise exposed to radiation 7 to form a second layer 12 of the photocured polymer on the first layer 11. This is repeated to form additional layers until the desired polishing layer is fully formed.

The viscosity of the reaction mixture at printing conditions can be from 0.01 Pascal-seconds (Pa·s) up to 20 Pa·s, or up to 10 Pa·s. Printing conditions can be at room temperature up to 200, up to 150, up to 100, up to 80, up to 50° C. but should be lower than the boiling points and thermal degradation points of the components of the reaction mixture. Room temperature printing conditions can be favored for energy efficiency. The reaction mixture can be in liquid form.

The method as disclosed herein can be used to provide a polishing surface with macro-texture (e.g., grooves, ridges, protrusions, depressions), microtexture (e.g., pores, lattice structures, network structures), or both. For example, grooves can be formed as long or continuous radial, concentric depressions from the polishing surface. The grooves can have depths, for example, of from 0.1, from 0.2, or from 0.3 mm up to 1.5, up to 1.2 or up to 1 mm. The grooves can have widths, for example, of from 0.05, from 0.1, from 0.2, or from 0.3 up to 1, up to 0.8 or up to 0.6 mm. The protrusions protrude above a based top surface of the polishing pad. The can be solid or open cylindrical, cubic, pyramidal or of an irregular cross section (e.g., lobed). The protrusions can have a height of from 0.05 or from 0.1 up to 2, or up to 1.5 mm. The protrusions can include openings in side walls. The protrustions can include a polishing surface raised above the top portion of the polishing layer on supports with a gap between the polishing surface and the top of the base of the polishing pad.

The chemical mechanical polishing pad as disclosed herein can include a subpad that is located opposite a polishing surface of the polishing layer. The polishing layer can be adhered to the subpad after the manufacturing of the subpad using an adhesive material. Alternatively, the entire pad can be formed by additive printing adjusting the composition of photosensitive reaction mixture used to form the subpad to provide the desired properties. The subpad material can be more compliant than the polishing layer. The subpad can comprise a porous layer. Alternatively, the subpad is an open network of interconnected structures.

Examples of polymeric materials for the subpad layer(s) include polyurethanes, polycarbonates, polysulfones, nylons, epoxy resins, polyethers, polyesters, polystyrenes, acrylic polymers, polymethyl methacrylates, polyvinylchlorides, polyvinyl fluorides, polyethylenes, polypropylenes, polybutadienes, polyethylene imines, polyether sulfones, polyamides, polyether imides, polyketones, silicones, copolymers thereof (such as, polyether-polyester copolymers), and combinations or blends thereof. The subpad can also be formed by additive manufacture as described herein. The subpad can be formed using thiol-ene curing from a reaction mixture as described herein that is selected to provide more compliance than is found in the polishing layer. The subpad can be formed from a reaction mixture having polymer precursors (monomers, oligomers, or mixtures thereof) with ethylenic unsaturated groups and thiol groups as described herein. If the subpad is formed by additive manufacture, the subpad and the polishing layer can be formed sequentially in the reaction vessel 1 with the reaction mixture being changed when moving from one layer to the other. For example, the polishing layer can be formed as described above. When the polishing layer is formed, the reaction mixture 10 can be removed from the vessel 1 and a new reaction mixture added. The same process of exposure to form additional layers on the polishing layer can occur. Alternatively, the subpad could first be formed and then the polishing layer formed by additive manufacture on the subpad as a substrate. For example, the subpad could be formed by additive manufacture, and then the process of forming the polishing layer on the subpad that is on the build platform occurs. As another example, a subpad that is preformed could be provided on the build platform, and the polishing layer formed on the subpad by additive manufacture as described herein.

The chemical mechanical polishing pad can include a window in the polishing layer. The window is formed of a material that is transparent to a wavelength used in end-point detection during the use of the polishing pad. The chemical mechanical polishing pad including a window can also be formed using additive manufacturing. For example, the polishing layer from the reaction mixture can be formed around a window material that is placed on the build platform. As another example, the polishing layer can be formed with an opening in which a window is later placed. As yet another alternative, the window itself can be formed by additive manufacture. For example, the window could first be formed by additive manufacture in the vessel 1 of the apparatus and then the polishing layer formed by additive manufacture around the window. As another example the polishing layer can be formed with a gap for the window by additive manufacture as disclosed herein and then the window can be formed by additive manufacture in the gap. The window material can be, for example, polyurethanes, acrylic polymers, cyclic olefin co-polymers (e.g., TOPAS 8007, etc.). Use of polyurethane materials can be helpful in pads where the polishing layer, subpad layer, or both are also polyurethanes. A specific set of examples of aliphatic polyurethanes for windows can be found, for example, in U.S. Pat. No. 10,293,456.

### EXAMPLES

In a prophetic example, a reaction mixture can comprise Component 1—small molecule (A) diallyl isophthalate (DAIP) or 2-hydroxyethyl acrylate (HEA); Component 2—an oligomeric molecule. A2x is a low molecular weight diol based prepolymer terminated with MDI and then reacted with HEA. A2y is derived from a PTMEG based pre-polymer terminated with TDI and then reacted with HEA; Component 3—a molecule (B) compound having more than 2 thiol functional groups to provide crosslinking where PTMP is pentaerythritol tetrakis(3-mercaptopropionate); Component 4—molecule (B) dithiol functional compound to provide chain extension where GDMP is ethylene glycol bis(3-mercaptopropionate) and HDT is 1,6-hexanedithiol; and diphenyl(2,4,6-trimethylbenzoyl) phosphine oxide (TPO) as a photoinitiator at 1 weight percent based on total weight of the reaction mixture. The amounts and identities of components 1-4 are shown in Table 1. Weight percents are based on total weight of the reaction mixture. All examples prepared with a mole ratio of 1:1 for the ethylenically unsaturated to the thiol groups.

TABLE 1

| Ex. | Component | Component 2 | Component 3-crosslinker | Component 4 |
|---|---|---|---|---|
| # | 1 (Wt %) | (Wt %) | (Wt %) | (Wt %) |
| 1 | DAIP | A2x | PTMP | GDMP |
| | (25%) | (35%) | (20%) | (20%) |
| 2 | HEA | A2x | PTMP | GDMP |
| | (31%) | (43%) | (0%) | (24%) |
| 3 | HEA | A2y | PTMP | HDT |
| | (33%) | (45%) | (0%) | (21%) |

This disclosure further encompasses the following aspects.

Aspect 1: A chemical mechanical polishing pad comprising a photocured polymer wherein the photocured polymer is the photoinitiated reaction product of a photocurable material comprising molecules having two or more functional groups wherein the functional groups include a thiol group and an ethylenically unsaturated group, provided for at least a portion of the molecules having the ethylenically unsaturated group, the ethylenically unsaturated group is a (meth)acrylate group, wherein the (meth)acrylate groups comprise less than 70 mole percent of total (meth)acrylate, thiol, and ethylenically unsaturated functional groups and wherein the photocure includes reaction of the thiol group with the ethylenically unsaturated group, provided at least some of the molecules comprise three or more functional groups.

Aspect 2. The chemical mechanical polishing pad of Aspect 1 wherein the molecules having two or more functional groups comprise first molecules having two or more of the ethylenically unsaturated groups and second molecules having two or more of the thiol groups, provided at least a portion of the first molecules comprise at least three or more ethylenically unsaturated groups or at least a portion of the second molecules comprise three or more thiol groups.

Aspect 3. The chemical mechanical polishing pad of Aspect 1 wherein the molecules include a heterotelechelic molecule having a (meth)acrylate group and a thiol group.

Aspect 4. The chemical mechanical polishing pad of any of the previous Aspects wherein the reaction mixture comprises a photoinitiator that generates a radical upon exposure to activating wavelengths of radiation.

Aspect 5. The chemical mechanical polishing pad of any of the previous Aspects wherein the reaction mixture comprises a photoinitiator that generates a base upon exposure to activating wavelengths of radiation.

Aspect 6. The method of Aspect 2 wherein the first molecule comprises the reaction product of a polyisocyanate comprising an oligomer, a multifunctional isocyanate monomer, or a mixture thereof and an (meth)acrylate functional end-capping agent.

Aspect 7. The chemical mechanical polishing pad of Aspect 2 wherein the first molecule comprises an oligomer comprising (meth)acrylate groups and the second molecule comprises one or more of alkyl multifunctional thiols, aromatic multifunctional thiols, thiol-terminated oligomers having two or more thiol groups.

Aspect 8. The chemical mechanical polishing pad of any of the previous Aspects comprising less than 0.05 weight percent of abrasive particles based on total weight of the polishing pad.

Aspect 9. The chemical mechanical polishing pad of any of the previous Aspects wherein the (meth)acrylate groups comprise less than 70 mole percent of the functional groups.

Aspect 10. A polishing pad of any of the previous Aspects formed from a method comprising providing the photocurable material in a vessel, selectively curing by irradiation a portion of the photocurable material to form a cured structure, selectively curing by irradiating an additional portion of the photocurable material to further build the cured structure, repeating the selective curing by irradiation until the cured structure has the form of an element of the polishing pad.

Aspect 11. The polishing pad of Aspect 10 wherein the wherein the molecules having two or more functional groups comprise a first molecule having two or more (meth)acrylate groups, wherein the first molecule is a monomer, an oligomer or a mixture of two or more thereof and a second molecule having two or more thiol groups, and the second molecule is a monomer, an oligomer, or a mixture thereof.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g. “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

What is claimed is:

1. A chemical mechanical polishing pad comprising a photocured polymer wherein the photocured polymer is the photoinitiated reaction product of a photocurable material comprising molecules having two or more functional groups wherein the functional groups include a thiol group and an ethylenically unsaturated group, provided for at least a portion of the molecules having the ethylenically unsaturated group, the ethylenically unsaturated group is a (meth)acrylate group, wherein the (meth)acrylate groups comprise less than 70 mole percent of total (meth)acrylate, thiol, and ethylenically unsaturated functional groups and wherein the photocure includes reaction of the thiol group with the ethylenically unsaturated group, provided at least some of the molecules comprise three or more functional groups.

2. The chemical mechanical polishing pad of claim 1 wherein the molecules having two or more functional groups comprise first molecules having two or more of the ethylenically unsaturated groups and second molecules having two or more of the thiol groups, provided at least a portion of the first molecules comprise at least three or more ethylenically unsaturated groups or at least a portion of the second molecules comprise three or more thiol groups.

3. The chemical mechanical polishing pad of claim 1 wherein the molecules include a heterotelechelic molecule having a (meth)acrylate group and a thiol group.

4. The chemical mechanical polishing pad of claim 1 wherein the reaction mixture comprises a photoinitiator that generates a radical upon exposure to activating wavelengths of radiation.

5. The chemical mechanical polishing pad of claim 1 wherein the reaction mixture comprises a photoinitiator that generates a base upon exposure to activating wavelengths of radiation.

6. The method of claim 2 wherein the first molecule comprises the reaction product of a polyisocyanate comprising an oligomer, a multifunctional isocyanate monomer, or a mixture thereof and an (meth)acrylate functional end-capping agent.

7. The chemical mechanical polishing pad of claim 2 wherein the first molecule comprises an oligomer comprising (meth)acrylate groups and the second molecule comprises one or more of alkyl multifunctional thiols, aromatic multifunctional thiols, multifunctional mercaptopropionate esters, multifunctional thioglycolate esters, multifunctional mercaptoacetate esters, thiol-terminated oligomers having two or more thiol groups.

8. The chemical mechanical polishing pad of claim 1 wherein the (meth)acrylate groups comprise less than 55 mole percent of total (meth)acrylate, thiol, and ethylenically unsaturated functional groups.

9. The polishing pad of claim 1 formed from a method comprising
providing a photocurable material in a vessel, selectively curing by irradiation a portion the photocurable material to form a cured structure, selectively curing by irradiating an additional portion of the photocurable material to further build the cured structure, repeating the selective curing by irradiation until the cured structure has the form of an element of the polishing pad.

10. The polishing pad of claim 9 wherein the photocurable material provided includes the following:
i) monomers or oligomers or mixtures thereof having two or more ethylenically unsaturated groups of which at least a portion of the ethylenically unsaturated groups are (meth)acrylate groups and
ii) monomers or oligomers or mixtures thereof having two or more thiol groups.
